(19) United States
(12) Patent Application Publication
(10) Pub. No.: US 2024/0254629 A1
(43) Pub. Date: Aug. 1, 2024

(54) SEMICONDUCTOR PROCESSING DEVICE WITH EDGE PURGING

(71) Applicant: ASM IP Holding B.V., Almere (NL)

(72) Inventors: Ankit Kimtee, Phoenix, AZ (US); Rohan Vijay Rane, Tempe, AZ (US); Herbert Terhorst, Amersfoort (NL); Eric James Shero, Phoenix, AZ (US); Jereld Lee Winkler, Gilbert, AZ (US); Michael Schmotzer, Chandler, AZ (US); Shuyang Zhang, Chandler, AZ (US); Todd Robert Dunn, Cave Creek, AZ (US); Shubham Garg, Gilbert, AZ (US)

(21) Appl. No.: 18/631,858

(22) Filed: Apr. 10, 2024

Related U.S. Application Data
(63) Continuation-in-part of application No. 18/087,871, filed on Dec. 23, 2022.
(60) Provisional application No. 63/266,099, filed on Dec. 28, 2021.

(51) Int. Cl. C23C 16/458; C23C 16/46

(52) U.S. Cl. CPC C23C 16/4586; C23C 16/46

(57) ABSTRACT

A susceptor assembly includes a heater pedestal and a cap coupled to the heater pedestal. The cap can include one or mor through holes to facilitate purging and/or reduce dead volumes associated with the susceptor assemblies. Reactor systems including such assemblies are also disclosed.

### CROSS-REFERENCE TO RELATED APPLICATIONS

This is a continuation-in-part of U.S. patent application Ser. No. 18/087,871, filed Dec. 23, 2022 and entitled “SEMICONDUCTOR PROCESSING DEVICE WITH WAFER EDGE PURGING,” which is a non-provisional of, and claims priority to and the benefit of, U.S. Provisional Patent Application No. 63/266,099, filed Dec. 28, 2021 and entitled “SEMICONDUCTOR PROCESSING DEVICE WITH WAFER EDGE PURGING,” which is hereby incorporated by reference herein.

### FIELD

The field generally relates to a processing apparatus and methods suitable in the formation of electronic devices. Additionally or alternatively, the field relates to susceptor assemblies and reactor systems that can be used in the manufacture of electronic devices, such as semiconductor devices.

### BACKGROUND

During semiconductor processing, various vaporized precursor(s) are fed into a reaction chamber. In some applications, suitable source chemicals that are in solid or liquid phase at ambient pressure and temperature are provided in a source vessel. These solid or liquid source substances may be heated to sublimation or evaporation to produce a vaporized precursor for a reaction process, such as vapor deposition. Chemical Vapor Deposition (CVD) may call for the supply of continuous streams of precursor vapor to the reaction chamber, while Atomic Layer Deposition (ALD), pulsed CVD and hybrids thereof may call for continuous streams or pulsed supply of one or more precursors to the reaction chamber, depending on the desired configuration.

During a chemical process within the reaction chamber, a substrate, such as a wafer, is typically placed on a susceptor. In some cases, the susceptor or an assembly including the susceptor can include small pockets or ridges that are difficult to purge and that can form dead spaces. Additionally, use of typical susceptor assemblies can lead to defects in devices formed using the substrate and/or undesired reaction with a backside of the substrate. Accordingly, improved susceptor assemblies and reactor systems are desired.

Any discussion of problems and solutions involved in the related art has been included in this disclosure solely for the purposes of providing a context for the present disclosure, and should not be taken as an admission that any or all of the discussion was known at the time the invention was made.

### SUMMARY

In view of the above-mentioned situation, one object of one or more aspects of the disclosed embodiments is to provide a susceptor assembly to eliminate or reduce any backside wafer reaction or deposition.

In some embodiments, the susceptor assembly may include a wafer support configured to support a wafer, which may comprise a wafer support body configured to support the wafer on a support surface of the wafer support body. The wafer support may further comprise a purge channel extending laterally from an inner portion of the wafer support body to an outer portion of the wafer support body and a first plenum channel disposed at the outer portion of the wafer support being in fluid communication with the purge channel, and an outlet to deliver purge gas to an edge of the wafer, said outlet is fluidly communicated with the first plenum channel. The susceptor assembly may further comprise a purge gas supply hole on a surface opposite to the support surface of the wafer support body, said purge gas supply hole being in fluid communication with the purge channel, and a plurality of first purge holes fluidly communicated with the first plenum channel and the purge channel. The wafer support may comprise a cylindrical body and the outlet may be concentric with the wafer support and a plurality of the purge channels extending symmetrically from the inner portion.

In some embodiments, the wafer support body may comprise a recess portion configured to support the wafer, and the outlet may be formed on the recess portion and in fluid communication with the first plenum. The wafer support may further comprise an annular ridge on the recess portion, and said annular ridge may be concentric with a circumference of the wafer to be treated. Said annular ridge may be configured to be disposed within a perimeter of the wafer to be treated. The outlet may be formed along an outermost periphery of the annular ridge. A depth of the recess portion at an outer diameter side of the annular ridge may be deeper than an inner diameter side of the annular ridge and progressively decreased toward a perimeter of the cylindrical body.

In some embodiments, a second plenum channel may be formed at the outer portion of the wafer support which is positioned vertically apart from the first plenum in a thickness direction of the wafer support body. The wafer support may further comprise a plurality of second purge holes fluidly communicated with the first plenum channel and the second plenum channel. The plurality of first purge holes may be fluidly communicated with the second plenum channel and respective purge channels. A number of the second purge holes may be greater than a number of the first purge holes.

In some embodiments, the susceptor assembly may be coupled to a shaft which comprises a vacuum tube and an inner gas supply tube, and a plurality of purge gas supply holes may be configured to be fluidly connected to an inert gas source through the inner gas supply tube. The wafer support body may comprise a Nickel-Chromium Molybdenum alloy. The susceptor assembly may further comprise a vacuum chuck groove disposed at the inner portion of the wafer support and a vacuum chuck hole in fluid communication with a plurality of vacuum chuck grooves through the vacuum tube. The vacuum chuck hole may be configured to be in fluid connection with a vacuum source. The wafer support body may comprise Hastelloy® C22® material.

In some embodiments, a susceptor assembly may comprise a wafer support configured to support a wafer, which may comprise a wafer support body configured to support a wafer to be treated, a plurality of purge channels extending laterally from an inner portion of the wafer support body to an outer portion of the wafer support body, a first plenum channel disposed at the outer portion of the wafer support, and a second plenum channel positioned vertically apart from the first plenum. The susceptor assembly may further comprise a second plenum channel which is in fluid communication with the plurality of purge channels by way of a plurality of first purge holes and in fluid communication with the first plenum by way of a plurality of second purge holes and an outlet in fluid communication with the first plenum to deliver purge gas to an edge of the wafer. The wafer support body may comprise a recess portion configured to support the wafer, and the outlet may be formed on the recess portion and in fluid communication with the first plenum. The susceptor assembly may be coupled to a shaft which comprises a purge gas supply tube connected to an inert gas source.

In some embodiments, a susceptor assembly may comprise a cap and a heater pedestal, wherein the cap comprises the wafer support and the surface opposite to the recess portion is configured to be disposed on a heater pedestal. The wafer support body may comprise a recess portion configured to support the wafer, and the outlet is formed on the recess portion and in fluid communication with the first plenum. The heater pedestal may be coupled to a shaft which comprises a vacuum tube and an inner gas supply tube. The heater pedestal may comprise one or more vacuum holes configured to couple to the respective vacuum chuck holes, and one or more purge gas holes configured to couple to the respective purge gas supply holes. The one or more vacuum holes may be configured to be fluidly connected to a vacuum source through the vacuum tube, and the one or more purge holes may be configured to be fluidly connected to an inner gas source through the inner gas supply tube. The susceptor assembly may comprises three temperature control zones which allows better tuning of the outer portion and improve within wafer (WiW)NU %.

Another object of one or more aspects of the present invention is to provide a showerhead assembly for treating a wafer which prevents or reduces back diffusion so that backside wafer deposition is eliminated or reduced.

In some embodiments, the showerhead assembly may comprise a showerhead plenum, a plurality of openings in fluid communication with the showerhead plenum, and an edge purge injection hole configured to be disposed outside of a perimeter of the wafer to be treated and in fluid communication with a purge gas source. The plurality of openings may be configured to convey vaporized precursor(s) from the showerhead plenum and onto a wafer support configured to support the wafer and the edge purge injection hole may be arranged to direct a purge gas to prevent back-diffusion of gases to the wafer.

In some embodiments, the showerhead assembly may include the plurality of edge purge injection holes that are directed circumferentially outwardly relative to the wafer to be treated. The showerhead assembly may further comprise a plurality of edge purge injection holes. The edge purge injection hole may not be in fluid communication with the showerhead plenum.

In some embodiments, a showerhead assembly, for treating a wafer, may comprise a showerhead plenum, a plurality of openings in fluid communication with the showerhead plenum, the plurality of openings configured to convey a vaporized precursor from the showerhead plenum and onto the wafer, and an edge purge injection hole configured to be disposed outside of a perimeter of the wafer to be treated and in fluid communication with a purge gas source. The purge gas may be directed circumferentially outwardly relative to the wafer support. The showerhead assembly may further comprise a plurality of edge purge injection holes.

In some embodiments, a showerhead assembly, for treating a wafer, may comprise a showerhead plenum, a substrate support configured to support the wafer, and a plurality of openings in fluid communication with the showerhead plenum and disposed over the substrate support. The plurality of openings may be configured to convey a vaporized precursor from the showerhead plenum and onto the wafer. A gap between the showerhead assembly and the substrate support may be narrower at an outer edge of the showerhead assembly than over the substrate support. The gap may be at least partially defined by a recess portion and a depth of the recess portion is progressively varied (e.g., decreased) toward an outer edge of the showerhead.

Yet another object of one or more aspects of the present invention is to provide a method for purging an edge of wafer.

In some embodiments, the method may include placing a wafer to be treated on a support surface of a wafer support, delivering a purge gas laterally along a purge gas channel of the wafer support to an outer portion of the wafer support, and directing the purge gas upwardly from the purge channel through a first plenum and through an outlet to an outer edge of the wafer. The method may further comprise holding the wafer onto the wafer support by applying vacuum to a vacuum chuck and applying precursor gas to the wafer. The purge gas may be directed from the purge channel through the first plenum, a second plenum and an outlet.

In some embodiments, the method may comprise placing a wafer to be treated on a substrate support, providing a precursor gas to the wafer from a showerhead, and delivering a purge gas through an edge purge injection hole outside of a perimeter of the wafer to be treated. The purge gas may be directed circumferentially outwardly.

In some embodiments, the method may comprise placing a wafer to be treated on a substrate support, providing a precursor gas to the wafer from a showerhead, and directing the precursor gas laterally relative to the showerhead through a gap between the showerhead and the substrate support, the gap narrower at an outer edge of the showerhead than over the wafer.

In accordance with yet further embodiments, a susceptor assembly, including a heater pedestal and a cap, is provided. In accordance with examples of these embodiments, the cap includes a top surface and a bottom surface. The bottom surface includes a recess to receive a top portion of the heater pedestal. The cap further includes one or more holes radially exterior of the recess, the holes extending from the top surface to the bottom surface. The top surface can further include a substrate recess to receive a substrate. The assembly can further comprise a seal. In such cases, the one or more holes can be radially inward of the seal. The cap can further include one or more vacuum chuck grooves and/or other features as described above and elsewhere herein.

In accordance with yet further embodiments, an assembly (e.g., a susceptor assembly) includes a heater pedestal, a cap coupled to the heater pedestal, the cap comprising a body comprising a top surface, a bottom surface, an inner region, an outer region, and one or more holes extending from the top surface to the bottom surface in the outer region, a flow control ring, and a seal between the flow control ring and the outer region.

In accordance with yet additional embodiments, a reactor system includes a reaction chamber and an assembly, such as a susceptor assembly and/or a showerhead assembly as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

The foregoing and other objectives and advantages may appear from the description to follow. In the description, reference is made to the accompanying drawings, which forms a part hereof, and in which is shown by way of illustration specific embodiments in which the disclosed embodiments may be practiced. These embodiments will be described in sufficient detail to enable those skilled in the art to practice the disclosed embodiments, and it is to be understood that other embodiments may be utilized and the structural changes may be made without departing from the scope of the disclosed embodiments. The accompanying drawings, therefore, are submitted merely as showing the preferred exemplification of the disclosed embodiments. Accordingly, the following detailed description is not to be taken in a limiting sense, and the scope of the disclosed embodiments is best defined by the appended claims.

FIG. 1 is a schematic diagram of an overview of the overall system of a semiconductor processing device.

FIG. 2 is a schematic diagram of a susceptor assembly in accordance with one embodiment.

FIG. 3 is a schematic diagram of a wafer support showing the purge channels.

FIG. 4 is a cross-sectional view of a single plenum embodiment taken along line A-A of FIG. 3.

FIG. 5 is a cross-sectional view of a dual plenum embodiment taken along line A-A of FIG. 3.

FIG. 6 is a schematic diagram of a susceptor assembly disposed on a heater pedestal in accordance with one embodiment.

FIG. 7 is a schematic diagram of a showerhead assembly with edge purge injection holes according to one embodiment.

FIG. 8 is a schematic diagram of a showerhead assembly with edge purge injection holes directed toward an outer circumferential side according to one embodiment.

FIG. 9 is a schematic diagram of a showerhead assembly without edge purge injection holes according to one embodiment.

FIG. 10 illustrates a reactor system in accordance with at least one embodiment of the disclosure.

FIG. 11 illustrates an assembly in accordance with at least one example of the disclosure.

FIG. 12 illustrates another assembly in accordance with at least one example of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

In the following detailed description, numerous specific details are set forth in order to provide a thorough understanding of the embodiments. However, it will be obvious to one with ordinary skill in the art that the embodiments may be practiced without these specific details. In other instances, well known methods, procedures, components, and mechanism have not been described in detail as not to unnecessarily obscure aspects of the present invention.

In general, in these apparatuses used in formation of a film in, for example, semiconductor manufacturing steps, a susceptor and heat source can be arranged under a substrate, such as a wafer, and a rear-surface heating method which can supply a uniform process gas from the top is used, which may create film growth on a backside of the wafer. During deposition processes, a high thickness on a wafer edge is observed for some processes due to backside deposition caused by back diffusion of precursors from a dead volume behind the wafer. Purging the wafer edge—e.g., from a periphery or backside of the wafer, will mitigate or eliminate deposition on the backside of the wafer and also allow better tuning of wafer edge thickness. In order to enable backside purge and secure the wafer to the susceptor during processing, a vacuum chucking susceptor or an electrostatic chucking susceptor can be provided to hold the wafer while purging the backside can be used. Additionally or alternatively, the susceptor can also comprise or serve as a heater to heat the wafer during processing.

For example, a vacuum chuck aluminum nitride (AlN) susceptor heater can be used; however, a dedicated edge purge channel may not be available with the AlN heater due to poor machinability and durability. A flow from the lower chamber caused by the pressure difference between upper and lower chambers can be utilized to prevent backside deposition. However, it is difficult to control the flow and only controlling a limited flow rate range can be provided using pressure differentials. Further, as the geometry of the AlN heater is a ceramic, the AlN heater generally cannot have an edge bias of greater than 10° C. without breakage and may have only a 2-zone temperature control. For certain processes, that causes degrading an emissivity and thickness non-uniformity (NU %), which cannot be recovered by outer zone susceptor temperature tuning. Thus, there is a need in the art for susceptor assembly that provides an enhancement of tuning of wafer edge thickness.

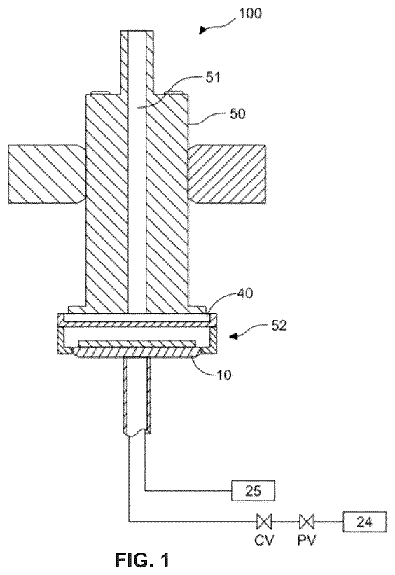

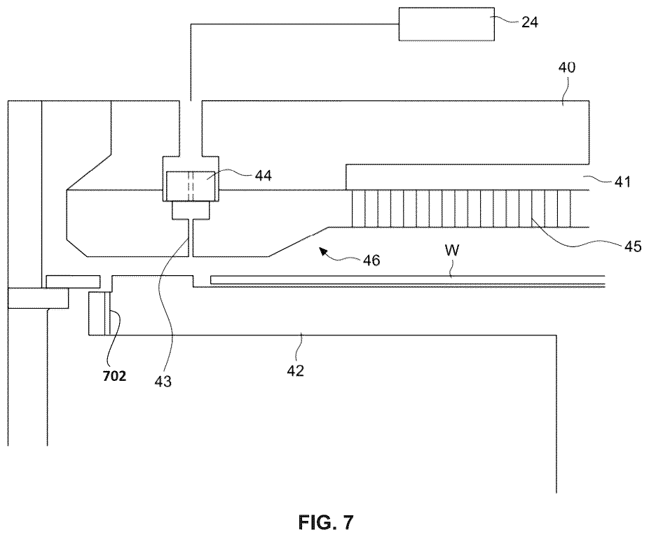

FIG. 1 is a schematic diagram of a semiconductor processing device 100 illustrating a manifold 50 as part of the overall semiconductor processing device 100. The manifold 50 can include a bore 51 that injects vaporized precursor downwards towards a showerhead assembly 40. It is understood that the manifold 50 can include multiple blocks connected together, or can comprise a unitary body. The manifold 50 can be connected upstream of a reaction chamber 52. In particular, an outlet of the bore 51 can communicate with a reactant injector, particularly the dispersion mechanism in the form of the showerhead assembly 40. As shown in FIGS. 7-9, the showerhead assembly 40 can include a showerhead plenum 41. The showerhead assembly 40 delivers the vapored precursor from the manifold 50 to a reaction space below the showerhead 40. The reaction chamber 52 includes a wafer support 10 configured to support a substrate W (e.g., a semiconductor wafer) in the reaction space. A vacuum source 25 may be coupled to the wafer support 10 for securing the wafer and an inert gas source 24 may be coupled to the wafer support for wafer edge purging through valves (CV, PV). While shown with a single-wafer, showerhead type of reaction chamber, the skilled artisan will appreciate that the manifold can also be connected to other types of reaction chambers with other types of injectors, e.g., batch or furnace type, horizontal or cross-flow reactor, etc.

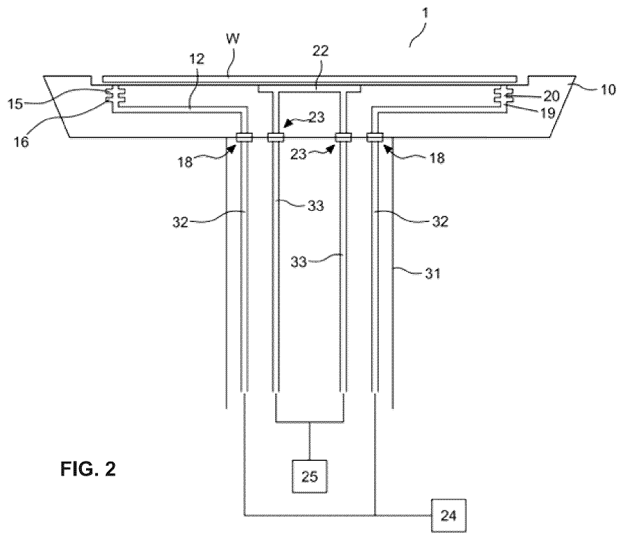

FIG. 2 is a schematic diagram of a susceptor assembly 1 in accordance with one embodiment. The susceptor assembly 1 can be configured to support a wafer W during a processing treatment (e.g., a deposition, etch, and/or clean process). The susceptor assembly 1 can comprise a wafer support 10, which may comprise a wafer support body 11 configured to support the wafer W to be treated on a support surface of the wafer support body 11. The support surface of the wafer support body 11 may comprise a recess portion to support the wafer W. The susceptor assembly 1 may further comprise a plurality of first purge holes 19 in fluid communication with the first plenum channel 15 and the purge channel 12.

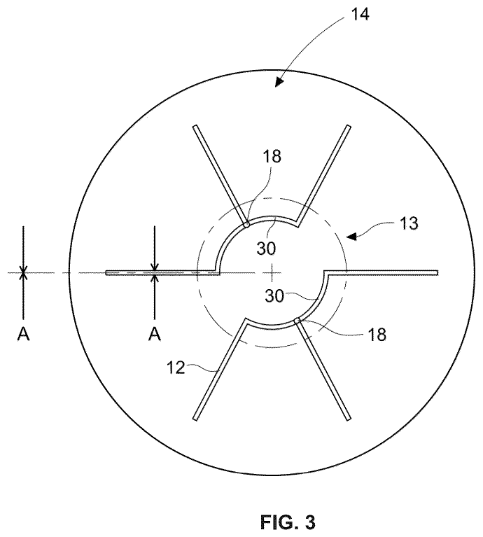

FIG. 3 is a schematic diagram of the wafer support 10 showing a purge channel 12 extending from an inner portion 13 to an outer portion 14 of the wafer support 10. The wafer support may comprise a plurality of the purge channels extending symmetrically from the inner portion.

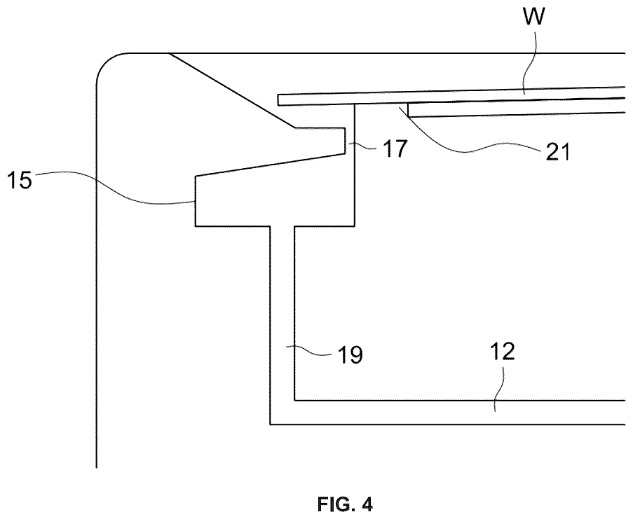

The wafer support 10 may further comprise one or more first plenum channels 15 formed at the outer portion 14 of the wafer support 10. As indicated in FIG. 4, an outlet 17 to deliver purge gas to the edge of the wafer W may be provided at or formed on the recess portion of the support surface of the wafer support body 11. The outlet 17 can be in fluid communication with the first plenum channel 15. One or more purge gas supply holes 18 (e.g., a plurality) can be formed on a surface of the wafer support 10 opposite to the recess portion of the support surface of the wafer support body 11 that supports the wafer W. The purge gas supply holes 18 can be in fluid communication with the plurality of purge channels 12 and respective inner gas supply tubes 32. The wafer support 10 may further comprise a plurality of first purge holes 19 in fluid communication with the first plenum channel 15 and the respective purge channels 12. The wafer support 10 may comprise a cylindrical or disc-shaped body and the outlet 17 may be concentric with the wafer support 10. The recess portion of the support surface of the wafer support body 11 may be shaped to receive the wafer W, such that the recess portion of the support surface of the wafer support body 11 may be generally circular in shape.

As shown in FIG. 3, the purge gas supply holes 18 may be formed on a surface opposite to the recess portion of the support surface of the wafer support body 11. The purge gas supply holes 18 can communicate with the plurality of purge channels 12 through one or more annular or arcuate-shaped channels 30. The plurality of purge channels 12 may radially extend from the annular or arcuate-shaped channels 30 disposed in the inner portion 13. In the illustrated embodiment, the purge channels 12 may extend symmetrically from the inner portion 13 for even distribution of the purge gas. A plurality of primary purge holes 19 can be disposed at an end of the respective purge channels 12 and in fluid communication with the first plenum channel 15, as shown in FIG. 4.

FIG. 4 illustrates the susceptor assembly with a single plenum channel, e.g., the first plenum channel 15. As shown in FIG. 4, an annular ridge 21 may be disposed on the recess portion of the support surface of the wafer support body 11 and may be concentric with a circumference of the wafer to be treated and configured to be disposed within a perimeter of the wafer W to be treated. The outlet 17 may be formed along an outermost periphery of the annular ridge 21 and may be fully opened around the circumference of the annular ridge 21. A depth of the recess portion of the support surface of the wafer support body 11 at an outer diameter side of the annular ridge 21 can be deeper than an inner diameter side of the annular ridge 21 and progressively decreased toward a perimeter of the cylindrical body.

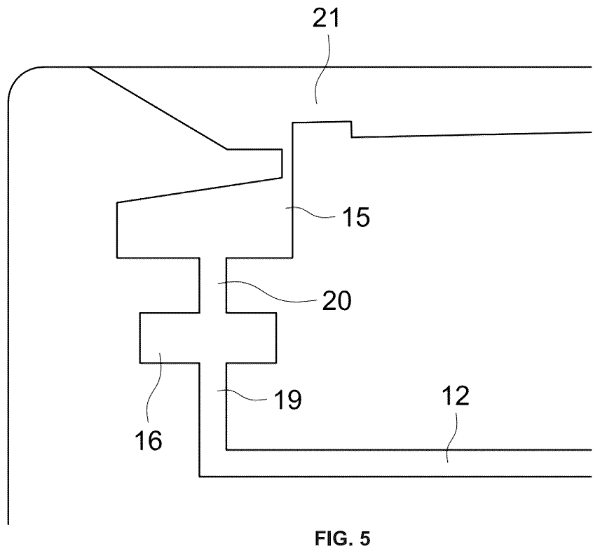

FIG. 5 illustrates a susceptor assembly with a plurality of plenum channels, e.g., the first plenum channel 15 and a second plenum channel 16. The second plenum channel 16 may be formed at the outer portion 14 of the wafer support 10, which is positioned vertically apart from the first plenum 15 in a thickness direction of the wafer support 10. The first plenum channel 15 and the second plenum channel 16 may be in fluid communication through a plurality of second purge holes 20 which may be formed through the body of the wafer support 10, as shown in FIGS. 2 and 5. The second plenum channel 16 allows the gases to combine for better distributed flow and can also provide a continuous fluid connection to the wafer edge by way of the outlet 17. Any number of the first purge holes 19 can be suitable but it may be preferable to have a large number of the purge holes for increasing uniformity. The plenums 15, 16 may be at least partially annular (e.g., completely annular) in shape, and may be configured to be disposed around the periphery of the wafer W to be treated. In some embodiments, a number of the first purge hole 19 may be equal to a number of symmetric purge channels 12 and a number of the second purge hole 20 may be greater than the number of the first purge hole 19. For example, the number of the first purge hole 19 and the number of symmetric purge channels 12 may be 6, while the number of the second purge hole 20 may be 36. The at least two purge gas supply holes 18 may be configured to be fluidly connected to the inert gas source 24.

The susceptor assembly 1 may be coupled to a shaft 31 which comprises a vacuum tube 33 and one or more inner gas supply tubes 32. The purge gas supply holes 18 may be configured to fluidly connect to the inert gas source 24 through the inner gas supply tube 32. The inert gas can be delivered from the inert gas source vertically upward through the supply tube 32 within the shaft and to the purge channels 12 through the supply holes 18. The inert gas may be delivered laterally outward to the plurality of primary purge holes 19 through the purge channels 12. The inert gas may be supplied to the first plenum 15 through the plurality of primary purge holes 19 and delivered to the second plenum channel 16 through the plurality of secondary purge holes 20 for the multiple plenum embodiment of FIG. 5. For the single plenum embodiment of FIG. 4, the channels 12 can convey the inert gas to the first plenum 15 by way of the purge holes 19. The delivered inert gas can be diffused through the outlet 17 to deliver a uniform flow to the edge of the wafer W. A narrow outlet design helps avoid dilution of the wafer edge. Beneficially, therefore, the disclosed embodiments can deliver an inert purge gas to the edge of the wafer to purge the backside of the wafer W of deposits.

The susceptor assembly 1 may further comprise one or more of a plurality of vacuum chuck grooves 22 disposed at the inner portion 13 of the wafer support 10. The plurality of vacuum chuck grooves 22 may be in fluid communication with at least two vacuum chuck holes 23 through vacuum tubes 32 in a shaft 31 so that the vacuum chuck grooves 22 apply suction to the wafer W to be treated. In other embodiments, the susceptor assembly 1 can comprise an electrostatic chuck to support the wafer W.

The wafer support 10 may comprise a Nickel-Chromium Molybdenum alloy having a good machinability and durability. The disclosed alloy can have a higher ramp rate per min compared to other materials (such as aluminum nitride (AlN)) for the susceptor heater, which allows a narrow slit design for outlet 17 to deliver a uniform flow to the edge of the wafer and a plurality of (e.g., three) temperature control zones, namely, the inner portion, outer portion and a portion therebetween, which allows better tuning of the outer portion and improve within wafer (WiW) non-uniformity (NU %). In some embodiments, the Nickel-Chromium Molybdenum alloy may comprise Hastelloy® C22® material, sold by Central States Industrial of Springfield, Missouri.

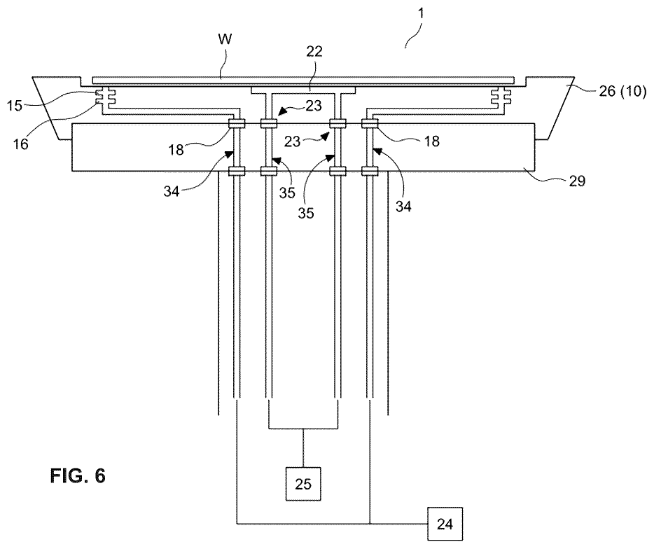

FIG. 6 illustrates another embodiment of the susceptor assembly 1. Unless otherwise noted, the components of FIG. 6 may be the same as or generally similar to like-numbered components of FIGS. 1-5. In the embodiment depicted in FIG. 6, the wafer support 10 can comprise a cap portion (or simply cap) 26 coupled to a heater pedestal 29. As shown, the surface of the cap portion 26 opposite to the recess portion of the support surface of the wafer support body 11 of the wafer support 10 may be configured to be disposed on the heater pedestal 29. The heater pedestal 29 may comprise one or more vacuum holes 35 configured to couple to the respective vacuum chuck holes 23, and one or more purge gas holes 34 configured to couple to the respective purge gas supply holes 18. The vacuum holes 35 may be configured to be in fluid communication with a vacuum source 25 and the purge gas holes 34 may be configured to be fluidly connected to an inert gas source 24. The heater pedestal 29 may comprise Nickel-Chromium Molybdenum alloy. The Nickel-Chromium Molybdenum alloy may comprise Hastelloy® C22© material. In this manner, an expensive and cumbersome cleaning process to remove deposits from the heater can be avoided and may eliminate the effect of wafer-heater dead volume. The cap 26 may be coupled to the heater pedestal 29 by any suitable way known in the art, e.g., by way of mechanical connectors, an adhesive, etc.

FIG. 7 illustrates another embodiment for preventing deposition of reactant gases onto the edge of the wafer W in a non-uniform manner. In FIG. 7, a showerhead assembly 40 (a gas distribution device) for treating the wafer W can be disposed over a substrate support 42. As discussed in more detail below, substrate support 42 can include one or more holes 702 to mitigate any dead spaces. The showerhead assembly 40 may comprise a showerhead plenum 41 disposed in an inner portion of the showerhead assembly 40 and a plurality of openings 45 formed on a surface facing the wafer W to be treated. The plurality of openings 45 are in fluid communication with the showerhead plenum 41 so that vaporized precursor(s) can be fed into the showerhead plenum 41 and deposited onto the wafer W through the plurality of openings 45. A plurality of edge purge injection holes 43 can be provided or formed on the surface facing the wafer W to be treated. The plurality of edge purge injection holes 43 may be located outside of a perimeter of the wafer W to be treated and in fluid communication with the inert gas source 24. In the illustrated embodiment, the edge purge injection holes 43 may be disposed outside of (and not exposed to) the showerhead plenum 41. The purge gas can be provided on the outside of a perimeter of the wafer W through an edge purge distribution perforated plate 44 so as to prevent a back diffusion from a desorption process that can migrate to the edge of the wafer W to create non-uniformity issue. The inert purge gas delivered to the edge of the wafer can beneficially create a curtain of inert gas to block back diffusion from exposing the wafer and dilutes precursor enough to lower or prevent backside deposition.

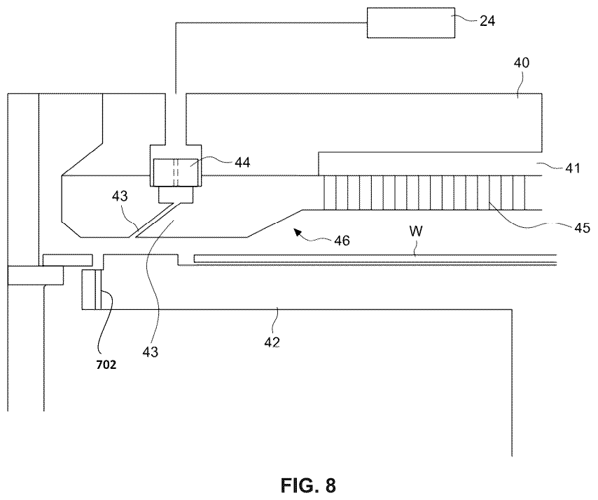

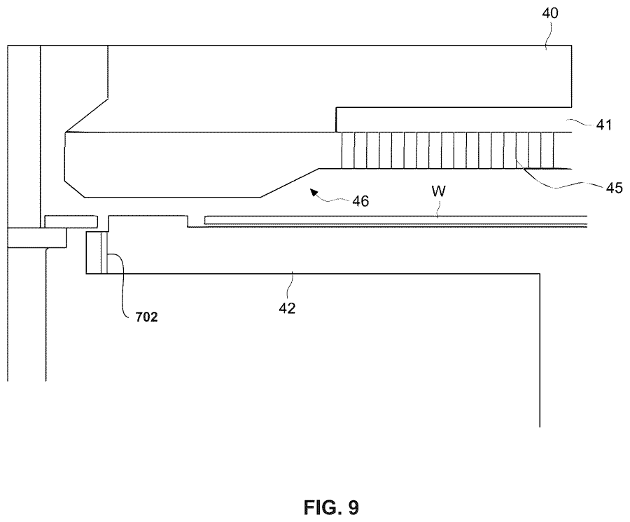

As shown in FIG. 8, the plurality of edge purge injection holes 43 may be directed toward an outer circumferential side so as to prevent back-diffusion than backside deposition. The edge purge injection holes 43 can be angled circumferentially outwardly so as to create a diffusion curtain to prevent back-diffusion of gases. Further, as indicated in FIG. 9, the showerhead assembly 40 may comprise a recess portion 46 and a depth of the recess portion can be progressively decreased toward an outer edge of the showerhead. The illustrated configuration provides a choke to compress the streamlines of gas so as to use velocity to stop back-diffusion without the edge purge injection holes 43. A gap between the showerhead assembly 40 and the substrate support can be narrower at an outer edge of the showerhead assembly 40 than over the substrate support. At the choked portion, a higher velocity and lower residence time of the vapored precursor can be achieved. Thus, the precursor can move faster, which may prevent non-uniform deposition of the precursor onto the wafer W.

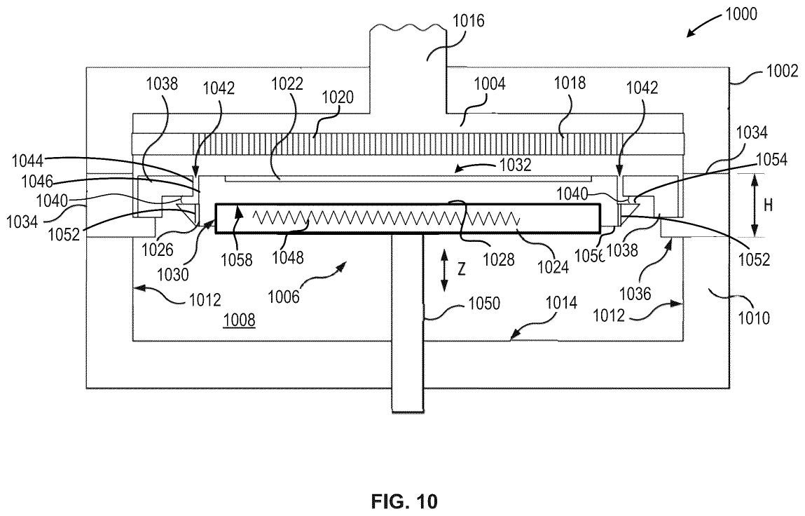

FIG. 10 illustrates another reactor system 1000 in accordance with additional embodiments of the disclosure. Reactor system 1000 can be similar to semiconductor processing device 100 described above, with exemplary distinctions noted below.

In the illustrated example, reactor system 1000 includes a reaction chamber 1002, a gas distribution device 1004, and a susceptor assembly 1006. Reactor system 1000 may further comprise an inlet 1016 to deliver various precursors to reaction chamber 1002.

Reaction chamber 1002 includes an interior space 1008 defined by a vertically-oriented sidewall 1010 having an interior-facing surface 1012 and a horizontally-oriented bottom surface 1014.

Gas distribution device 1004 can be or include a showerhead assembly. In the illustrated example, gas distribution device 1004 includes a plate 1018 comprising a plurality of through-holes 1020 configured to flow precursor from the inlet 1016 toward a substrate 1022. Gas distribution device 1004 may be positioned adjacent to and supported by the sidewall 1010. In various embodiments, gas distribution device 1004 may be separated from the sidewalls 1010. In accordance with other examples, gas distribution device 1004 can be or include another showerhead assembly, such as the showerhead assemblies described above in connections with any of FIGS. 7-9.

Susceptor assembly 1006 can include a heater pedestal 1024 and a cap 1026 coupled to (e.g., disposed on top of) heater pedestal 1024. Susceptor cap 1026 may completely cover a top surface 1028 of heater pedestal 1024. Further, susceptor cap 1026 may extend down and around a perimeter edge 1030 of the heater pedestal 1024. Further, susceptor cap 1026 may extend away from the perimeter edge 1030 and toward sidewall 1010 of the reaction chamber 1002. In various embodiments, the susceptor cap 1026 may comprise a substrate recess 1032 to receive substrate 1022. In various embodiments, susceptor cap 1026 may be formed from a metal or other materials noted herein in connection with caps, chucks, and/or wafer/substrate supports.

In various embodiments, reaction chamber 1002 may further comprise a spacer plate 1034 integrated within or attached to sidewall 1010. Spacer plate 1034 may be defined by a region of the sidewall that meets or is proximate gas distribution device 1004 and may have a height H that is based on the dimensions (e.g., height) of heater pedestal 1024 and/or cap 1026. In various embodiments, spacer plate 1034 may further comprise a lip 1036 that extends away from the interior-facing surface 1012 and into the interior space 1008. Lip 1036 may extend around the entire perimeter of the interior space 1008.

Reaction chamber 1002 may further comprise a flow control ring 1038 adjacent to the spacer plate 1034. In some embodiments, flow control ring 1038 may rest on the lip 1036 of the spacer plate 1034, such that the flow control ring 1038 may move relative to spacer plate 1034. In other words, the flow control ring 1038 may not be fixed or bonded to the spacer plate 1034. However, in other embodiments, flow control ring 1038 may be fixed or bonded to spacer plate 1034, such that flow control ring 1038 does not move relative to spacer plate 1034.

In various embodiments, and in cases where a susceptor cap is used, flow control ring 1038 may be adjacent to cap 1026 (e.g., when heater pedestal 1024 is in the up-most position). In some cases, a seal 1040 is disposed between cap 1026 and flow control ring 1038. Seal 1040 can be formed of any suitable material, such as a metal (e.g., stainless steel or nickel alloys). In some cases, flow control ring 1038 may be separated from cap 1026 by a gap 1042. Gap 1042 may be formed by a side surface 1044 of flow control ring 1038 and a side surface 1046 of cap 1026. Gap 1042 can range from, for example, 0 mm or greater than 0 mm to about 1 mm.

In various embodiments, and in cases where a susceptor cap is not used, flow control ring 1038 may be adjacent to, in contact with, separated by a gap, or separated by a seal, as described above, relative to heater pedestal 1024 (when heater pedestal 1024 is in the up-most position).

Heater pedestal 1024 may suitably include one or more resistive heaters 1048. Such resistive heaters can be embedded within heater pedestal 1024. Heater pedestal 1024 can also include a shaft 1050, which can be the same or similar to shaft 31 described above.

As illustrated in FIG. 10, cap 1026 includes one or more holes 1052 that extend from a top surface 1054 to a bottom surface 1056 of cap 1026. As illustrated, one or more holes 1052 may suitably be exterior of a recess 1058 that is configured to receive a top portion (e.g., including top surface 1028) of heater pedestal 1024. A number of holes can be, for example, between about 12 and about 72 holes. A diameter of each of the one or more holes can be, for example, not less than 0.5 mm and not greater than 1.5 mm.

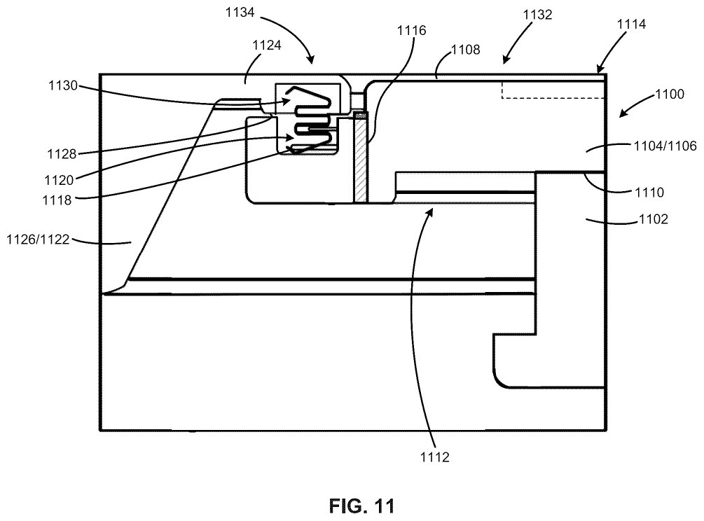

FIG. 11 illustrates a portion of another susceptor assembly 1100 in accordance with additional embodiments of the disclosure. Susceptor assembly 1100 can be used in connection with semiconductor processing device 100 or reactor system 1000 described above. Susceptor assembly 1100 includes a heater pedestal 1102 and a cap 1104 coupled to heater pedestal 1102.

Cap 1104 includes a body 1106 comprising a top surface 1108 and a bottom surface 1110. Bottom surface 1110 comprises a recess 1112 to receive a top portion of the heater pedestal 1102 and may also include a substrate recess 1114 to receive a substrate. Similar to cap 1026, cap 1104 includes one or more holes 1116 radially exterior recess 1112, the one or more holes extending from top surface 1108 to bottom surface 1110. The number of holes can be as noted above. Cap 1104 also includes an inner region 1132 and an outer region 1134. As illustrated, a height of inner region 1132 can be greater than a height of the outer region 1134. One or more holes 1116 can be located within outer region 1134. The one or more holes 1116 can be used to mitigate dead space that might otherwise form between cap 1104 and a flow control ring 1122.

In the illustrated example, susceptor assembly 1100 includes a seal 1118, which can be the same or similar to seal 1040. Seal 1118 can be in the form of, for example, an annular metal spring.

In accordance with examples of these embodiments, top surface 1108 of cap 1104 includes a seal recess 1120 (e.g., in outer region 1134) configured to receive a portion of seal 1118. By way of example, recess 1120 can be an annular ring or partial annual structure. As illustrated, one or more holes 1116 can be radially inward seal recess 1120. The number and size of holes can be as described above in connection with FIG. 10.

In accordance with further examples, assembly 1100 can include flow control ring 1122, which can be similar to flow control ring 1038. In the example illustrated in FIG. 11, flow control ring 1122 includes an (e.g., annular) arm 1124 extending from flow control ring body 1126.

As illustrated, arm 1124 includes a bottom surface 1128 that includes a ring recess 1130. Ring recess 1130 can suitably be configured to receive a portion of seal 1118.

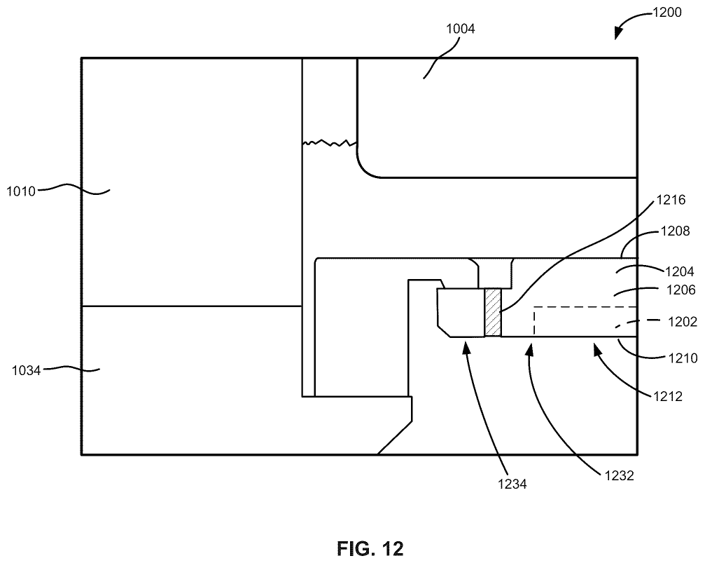

FIG. 12 illustrates another susceptor assembly 1200 in accordance with examples of the disclosure. Susceptor assembly 1200 is similar to susceptor assembly 1100, except susceptor assembly 1200 may not include seal 1118 and/or recess 1120 and/or recess 1130.

Susceptor assembly 1200 can be used in connection with semiconductor processing device 100 or reactor system 1000 described above. Susceptor assembly 1200 includes a heater pedestal 1202 and a cap 1204 coupled to heater pedestal 1202.

Similar to cap 1104, cap 1204 includes a body 1206 comprising a top surface 1208 and a bottom surface 1210. Bottom surface 1210 comprises a recess 1212 to receive a top portion of the heater pedestal 1202 and may also include a substrate recess as described above to receive a substrate. Similar to cap 1104, cap 1204 includes one or more holes 1216 radially exterior recess 1212, the one or more holes extending from top surface 1208 to bottom surface 1210. The number of holes and the size of the holes can be as noted above. Cap 1204 also includes an inner region 1232 and an outer region 1234. As illustrated, a height (distance between top surface 1108 and bottom surface 1110) of inner region 1232 can be greater than a height of the outer region 1234. One or more holes 1216 can be located within outer region 1234.

FIGS. 10-12 illustrate susceptor assemblies with holes spanning a height of a cap. In accordance with other examples of the disclosure, the susceptor assemblies may not include a cap. In such cases, the holes as described above can span between a top and bottom surface of a heater pedestal.

Various features of illustrated embodiments can be combined. For example, the susceptor assemblies (e.g., a cap thereof) illustrated in FIGS. 10-12 can include one or more vacuum chuck grooves and/or purge gas channels within a body, as illustrated in FIG. 3. Additionally or alternatively, the cap and/or heater pedestal can include a purge gas hole as described above in connection with FIGS. 2-6.

The present disclosure also relates to methods for purging an edge of wafer using the susceptor assembly or showerhead assembly described herein, such as semiconductor wafers, in gas-phase reactors, such as chemical vapor deposition (CVD) reactors, including plasma-enhanced CVD (PECVD) reactors, low-pressure CVD (LPCVD) reactors, atomic layer deposition (ALD) reactors, and the like. By way of examples, the assemblies and components described herein can be used in showerhead-type gas-phase reactor systems, in which gases generally flow in a downward direction from a showerhead and toward a substrate.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language, such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted fairly based on the language employed in the claims and not limited to the examples described in the present specification or during the prosecution of the application, which examples are to be construed as non-exclusive.

What is claimed is:

1. A susceptor assembly comprising:
a heater pedestal; and
a cap coupled to the heater pedestal, the cap comprising a body comprising a top surface and a bottom surface,
wherein the bottom surface comprises a recess to receive a top portion of the heater pedestal, and
wherein the cap comprises one or more holes radially exterior the recess, the one or more holes extending from the top surface to the bottom surface.

2. The susceptor assembly of claim 1, wherein the top surface comprises a substrate recess to receive a substrate.

3. The susceptor assembly of claim 1, further comprising a seal,
wherein the top surface comprises a seal recess to receive the seal.

4. The susceptor assembly of claim 3, wherein the seal comprises metal.

5. The susceptor assembly of claim 3, wherein the one or more holes are radially inward the seal recess.

6. The susceptor assembly of claim 1, wherein the cap comprises between 12 and 72 holes.

7. The susceptor assembly of claim 1, wherein a diameter of each of the one or more holes is not less than 0.5 mm and not greater than 1.5 mm.

8. The susceptor assembly of claim 1, wherein the cap further comprises one or more vacuum chuck grooves within the body.

9. The susceptor assembly of claim 1, wherein the cap comprises a purge gas channel within the body and extending laterally.

10. The susceptor assembly of claim 9, wherein the heater pedestal comprises a purge gas hole.

11. The susceptor assembly of claim 1, wherein the cap comprises an inner region and an outer region, wherein a height of the inner region is greater than a height of the outer region.

12. The susceptor assembly of claim 11, wherein the one or more holes are located within the outer region.

13. An assembly comprising:
a heater pedestal;
a cap coupled to the heater pedestal, the cap comprising a body comprising a top surface, a bottom surface, an inner region, an outer region, and one or more holes extending from the top surface to the bottom surface in the outer region;
a flow control ring; and
a seal between the flow control ring and the outer region.

14. The assembly of claim 13, wherein the outer region comprises a seal recess to receive a portion of the seal.

15. The assembly of claim 14, wherein the one or more holes are radially inward the seal recess.

16. The assembly of claim 13, wherein the seal comprises metal.

17. The assembly of claim 13, wherein the cap comprises a purge gas channel within the body and extending laterally.

18. The assembly of claim 17, wherein the heater pedestal comprises a purge gas hole.

19. The assembly of claim 13, wherein a height of the inner region is greater than a height of the outer region.

20. A reactor system comprising:
a reaction chamber; and
a susceptor assembly within the reaction chamber, the susceptor assembly comprising:
a heater pedestal; and
a cap coupled to the heater pedestal, the cap comprising a body comprising a top surface and a bottom surface,
wherein the bottom surface comprises a recess to receive a top portion of the heater pedestal, and
wherein the cap comprises one or more holes radially exterior the recess, the one or more holes extending from the top surface to the bottom surface.
